(19) United States
(12) Patent Application Publication
(10) Pub. No.: US 2022/0385168 A1
(43) Pub. Date: Dec. 1, 2022

(54) VOLTAGE CONVERSION APPARATUS

(71) Applicant: Mitsubishi Electric Corporation, Tokyo (JP)

(72) Inventors: Shinichi KIMINAMI, Tokyo (JP); Yasuhiko KANNAN, Tokyo (JP)

(73) Assignee: Mitsubishi Electric Corporation, Tokyo (JP)

(21) Appl. No.: 17/504,756

(22) Filed: Oct. 19, 2021

(30) Foreign Application Priority Data
May 27, 2021 (JP) 2021-088910

(51) Int. Cl. H02M 1/14; H02M 3/155

(52) U.S. Cl. CPC H02M 1/143; H02M 3/155

(57) ABSTRACT

The voltage conversion apparatus includes a voltage holding unit that holds a maximum voltage of an output voltage and a determination unit that determines whether or not the maximum voltage held by the voltage holding unit is within a predetermined voltage range; when starting control of opening/closing operation by an opening/closing device, a control unit makes the opening/closing device perform the opening/closing operation, based on a predetermined starting switching frequency and a predetermined starting duty; the determination unit detects a failure in a smoothing capacitor by determining that the held maximum voltage is out of the voltage range.

### BACKGROUND OF THE INVENTION

### Field of the Invention

The present disclosure relates to a voltage conversion apparatus.

### Description of the Related Art

In general, a voltage conversion apparatus is configured in such a way as to convert a supplied voltage into a predetermined voltage so as to supply electric power to a microcomputer (hereinafter, referred to as a MICON), a control circuit, or the like. In the case where conversion of a supplied voltage into a voltage higher than that, i.e., voltage stepping-up is performed, a switching-type voltage conversion apparatus is utilized. In addition, even in the case where voltage stepping-down is performed, a switching-type voltage conversion apparatus may be utilized in view of an allowable ripple voltage of a MICON, a control circuit, or the like, or in view of power saving.

As is well known, a switching-type voltage conversion apparatus is configured to perform voltage conversion by intermittently energizing an induction device through opening/closing operation of an opening/closing device and accumulating induction energy produced in the induction device in a smoothing capacitor; however, there exists a probability that due to a failure of the smoothing capacitor caused by aging deterioration or due to a connection failure caused by a solder crack that occurs in a solder portion where a terminal of the smoothing capacitor is connected with an electric circuit, the smoothing operation by the smoothing capacitor cannot be performed, a predetermined voltage cannot be obtained, and hence an excessive voltage or current makes the failure spread throughout the apparatus.

To date, in order to detect a failure in a smoothing capacitor, various types of failure detection means or methods have been utilized. For example, Patent Document 1 has disclosed a technology in which when a control apparatus is turned off, a step-up circuit makes a discharging circuit operate so that based on a monitor value of a step-up capacitor at a time when the discharging operation has started and a monitor value of the step-up capacitor at a time when a predetermined time has elapsed after the starting time of the discharging operation, an MPU (Micro Processor Unit) diagnoses a deterioration or a failure in the step-up capacitor and checks the operation of the discharging circuit.

In addition, Patent Document 2 has disclosed a technology in which during operation of a power source apparatus, a ripple component in the output voltage to be smoothed by a capacitor is detected by a peak detector and an average-value detector and in which when the ripple component exceeds a predetermined value, a capacitor-life-time-information supply apparatus determines that the life time of the capacitor has been exhausted and then provides notification of the fact by means of a sound or a display.

### PRIOR ART REFERENCE

### Patent Document

[Patent Document 1] International Publication No. 2016/031509

[Patent Document 2] Japanese Patent Application Laid-Open No. 2006-133046

### SUMMARY OF THE INVENTION

The conventional technology disclosed in Patent Document 1 makes possible that by making a discharging circuit operate for diagnosing a step-up capacitor, not only a diagnosis on a deterioration or a failure in the step-up capacitor but also an operation check on the discharging circuit to be utilized in the event of an emergency is performed; however, the discharging circuit for a failure diagnosis is required and hence the circuit scale increases; thus, it is difficult to downsize the apparatus and to reduce the cost.

Moreover, the conventional technology disclosed in Patent Document 2 makes it possible that by detecting the amplitude value of a ripple generated between the both terminals of a capacitor during operation of a power source apparatus, an increase in the inner impedance and capacity exhaustion due to aging deterioration are diagnosed; however, in the case where the smoothing capacitor has an open failure before the power source apparatus is started, an excessive voltage is generated and hence other circuits connected with the power source apparatus may be broken; in the case where the smoothing capacitor has a short-circuit failure before the power source apparatus is started, an excessive current is generated and hence the opening/closing device may be broken.

The present disclosure is to disclose a technology for solving the foregoing problems; the objective thereof is to provide a voltage conversion apparatus that does not make a failure spread throughout the apparatus even when the smoothing capacitor fails and that realizes downsizing and cost saving.

A voltage conversion apparatus disclosed in the present disclosure includes

a switching regulator having
an induction device that is intermittently energized through opening/closing operation by an opening/closing device so as to produce induction energy,
a smoothing capacitor that accumulates the induction energy produced by the induction device and smooths the induction energy, and
a control unit that controls opening/closing operation by the opening/closing device,

a voltage holding unit that holds a maximum voltage of the output voltage, and

a determination unit that determines whether or not the maximum voltage held by the voltage holding unit is within a predetermined voltage range; the switching regulator converts an input voltage supplied from an outside into a predetermined voltage to be outputted as an output voltage; when starting control of opening/closing operation by the opening/closing device, the control unit makes the opening/closing device perform the opening/closing operation, based on a predetermined starting switching frequency and a predetermined starting duty; the determination unit detects a failure in the smoothing capacitor by determining that the held maximum voltage is out of the voltage range.

The present disclosure makes it possible to obtain a voltage conversion apparatus that does not make a failure spread throughout the apparatus even when a capacitor fails and that realizes downsizing and cost saving.

The foregoing and other object, features, aspects, and advantages of the present invention will become more apparent from the following detailed description of the present invention when taken in conjunction with the accompanying drawings.

### BRIEF DESCRIPTION OF THE DRAWINGS

FIG. 1 is a configuration diagram representing the configuration of a voltage conversion apparatus according to Embodiment 1;

FIG. 2 is a configuration diagram representing the configuration of a variant example of the voltage conversion apparatus according to Embodiment 1;

FIG. 3A is a set of explanatory charts for explaining operation by the voltage conversion apparatus according to Embodiment 1;

FIG. 3B is a set of explanatory charts for explaining operation by the voltage conversion apparatus according to Embodiment 1;

FIG. 3C is a set of explanatory charts for explaining operation by the voltage conversion apparatus according to Embodiment 1;

FIG. 4 is a configuration diagram representing the configuration of a voltage conversion apparatus according to Embodiment 2;

FIG. 5A is a set of explanatory charts for explaining operation by the voltage conversion apparatus according to Embodiment 2;

FIG. 5B is a set of explanatory charts for explaining operation by the voltage conversion apparatus according to Embodiment 2; and

FIG. 5C is a set of explanatory charts for explaining operation by the voltage conversion apparatus according to Embodiment 2.

### DETAILED DESCRIPTION OF THE PREFERRED EMBODIMENTS

### Embodiment 1

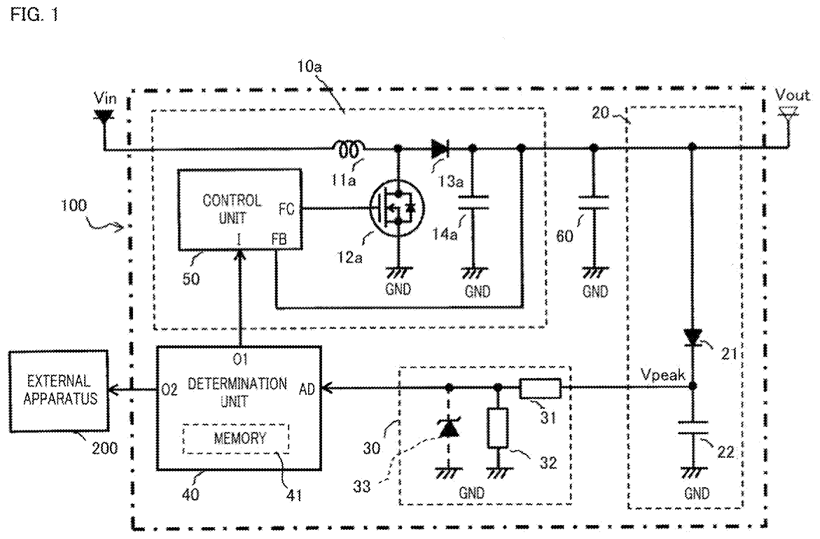

FIG. 1 is a configuration diagram schematically representing the overall configuration of a voltage conversion apparatus according to Embodiment 1. In FIG. 1, a voltage conversion apparatus 100 mainly includes a switching regulator 10a, a voltage holding unit 20, a voltage dividing circuit 30, a determination unit 40, and an auxiliary capacitor 60 and is connected with an external apparatus 200 at the outside thereof.

The switching regulator 10a steps up an input voltage Vin to a predetermined output voltage Vout, and is a step-up chopper circuit including an induction device 11a, an opening/closing device 12a, a rectifying device 13a, a smoothing capacitor 14a, and a control unit 50. The control unit 50 is a so-called PWM controller that performs a PWM (Pulse Width Modulation) modulation so that a voltage inputted to a feedback terminal FB becomes a predetermined voltage and then outputs a pulse signal from an output terminal FC; the control unit 50 has a function of permitting or prohibiting output of the pulse signal in accordance with a signal inputted to an input terminal I.

The smoothing capacitor 14a is to smooth induction energy produced through opening/closing operation by the opening/closing device 12a; thus, it is desirable to adopt a capacitor such as an electrolytic capacitor whose capacity can readily be increased. In Embodiment 1, the rectifying device 13a is a diode. It may be allowed that the rectifying device 13a is configured in another manner such as a synchronous rectification method utilizing a MOS-FET (Metal Oxide Semiconductor Field Effect Transistor). This can be applied also to Embodiment 2, described later. In addition, in the case of the step-up switching regulator 10a represented in FIG. 1, it is desirable that the opening/closing device 12a is an N-type MOS-FET that can readily be driven.

The voltage holding unit 20 is to hold the maximum voltage out of output voltages, inputted thereto, of the switching regulator 10a and to output the maximum voltage; the voltage holding unit 20 is configured with a series unit including a rectifying device 21 and a voltage holding capacitor 22. In addition, the voltage holding unit 20 may be configured in any other manner, as long as it is configured to hold and output the maximum voltage out of inputted voltages This can be applied also to Embodiment 2, described later.

The voltage diving circuit 30 is to output a voltage proportional to an inputted voltage and is configured with a series unit including a first division resistor 31 and a second division resistor 32; the voltage dividing circuit 30 is configured to expand an AD measurement range with which an analogue signal inputted to an input terminal AD of the determination unit 40 is converted into a digital signal and is determined. It may be allowed that a Zener diode 33 is added to the output stage of the voltage dividing circuit 30 so as to limit the voltage to be outputted from the voltage dividing circuit. In addition, it may be allowed that the voltage dividing circuit 30 is omitted, depending on the input-voltage range, the accuracy thereof, and the like of the after-mentioned determination unit 40 to be connected with the output stage thereof. This can be applied also to Embodiment 2, described later.

The determination unit 40 is configured in such a way as to determine whether or not a voltage inputted from the voltage dividing circuit 30 is within a normal voltage range Vrng as a predetermined voltage range; when it determines that the voltage inputted from the voltage dividing circuit 30 is not within the predetermined normal voltage range Vrng, the determination unit 40 determines that there exists an abnormality, and then outputs a signal based on the determination result to the inside and the our of the voltage conversion apparatus 100. The normal voltage range Vrng is a voltage range at a time when an inputted voltage is normal; thus, the voltage range at a time when the voltage inputted from the voltage dividing circuit 30 is normal and the voltage range at a time when in the case where no voltage dividing circuit 30 is provided, the voltage inputted is normal have respective different value, as a matter of course.

The determination unit 40 is a MICON provided, for example, with an output terminal O1 for outputting an instruction signal, an output terminal O2 for outputting an abnormality notification signal, the input terminal AD to which an analogue signal is inputted, and a memory 41 in which a setting value for the normal voltage range Vrng is stored; the determination unit 40 stores the normal voltage range Vrng in the memory 41. The determination unit 40 is configured in such a way that the normal voltage range Vrng can arbitrarily be set by rewriting a normal voltage range stored in the memory 41.

The auxiliary capacitor 60 supports the smoothing operation by the smoothing capacitor 14a and is configured in such a way as to suppress the output voltage of the switching regulator 10a from steeply rising, even when an open failure occurs in the smoothing capacitor 14a.

In FIG. 1, the determination unit 40 and the control unit 50 are configured in such a way as to be separate from each other; however, it may be allowed that at least part of one of the determination unit 40 and the control unit 50 is included in the other thereof. This can be applied also to Embodiment 2, described later.

The external apparatus 200 is, for example, a monitoring apparatus higher in a hierarchy than the voltage conversion apparatus 100 and is configured to monitor the state of the voltage conversion apparatus 100.

Next, connection relationships in the voltage conversion apparatus 100 represented in FIG. 1 will be explained. The input voltage Vin is applied to one end of the induction device 11a. The other end of the induction device 11a is connected with the drain terminal of the opening/closing device 12a and with the anode terminal of the rectifying device 13a. The source terminal of the opening/closing device 12a is connected with a reference electric potential GND. The gate terminal of the opening/closing device 12a is connected with the output terminal FC of the control unit 50.

The cathode terminal of the rectifying device 13a is connected. with one end of the smoothing capacitor 14a, the feedback terminal FB of the control unit 50, one end of the auxiliary capacitor 60, and the anode terminal of the rectifying device 21; the output voltage Vout outputted from the cathode terminal of the rectifying device 13a is applied to the foregoing respective portions connected with the cathode terminal of the rectifying device 13a. Unrepresented circuit devices are connected with the output voltage Vout. The other end of the smoothing capacitor 14a and the other end of the auxiliary capacitor 60 are connected with the reference electric potential GND.

The cathode terminal of the rectifying device 21 is connected with one end of the voltage holding capacitor 22 and one end of the first division resistor 31. The other end of the voltage holding capacitor 22 is connected with GND. The other end of the first division resistor 31 is connected with one end of the second division resistor 32, the input terminal AD of the determination unit 40, and the cathode terminal of the Zener diode 33 (when provided). The other end of the second division resistor 32 and the anode terminal of the Zener diode 33 are connected with GND. The output terminal O2 of the determination unit 40 is connected with the external apparatus 200. The output terminal O1 of the determination unit 40 is connected with the input terminal I of the control unit 50.

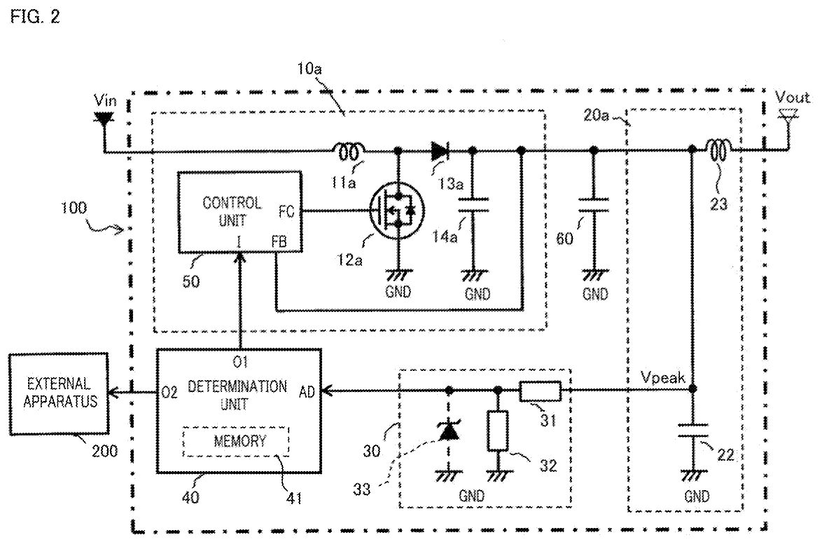

FIG. 2 is a configuration diagram representing the configuration of a variant example of the voltage conversion apparatus according to Embodiment 1. The voltage conversion apparatus 100 according to Embodiment 1 represented in FIG. 2 and the voltage conversion apparatus 100 according to Embodiment 1 represented in foregoing FIG. 1 lies only in the respective configurations of the voltage holding units; the other configurations are one and the same. In FIG. 2, a voltage holding unit 20a does not utilize the rectifying device 21 utilized by the voltage holding unit 20 in FIG. 1 but utilizes an induction device 23; the induction device 23 suppresses electric charges accumulated in the voltage holding capacitor 22 from leaking to the other circuit devices.

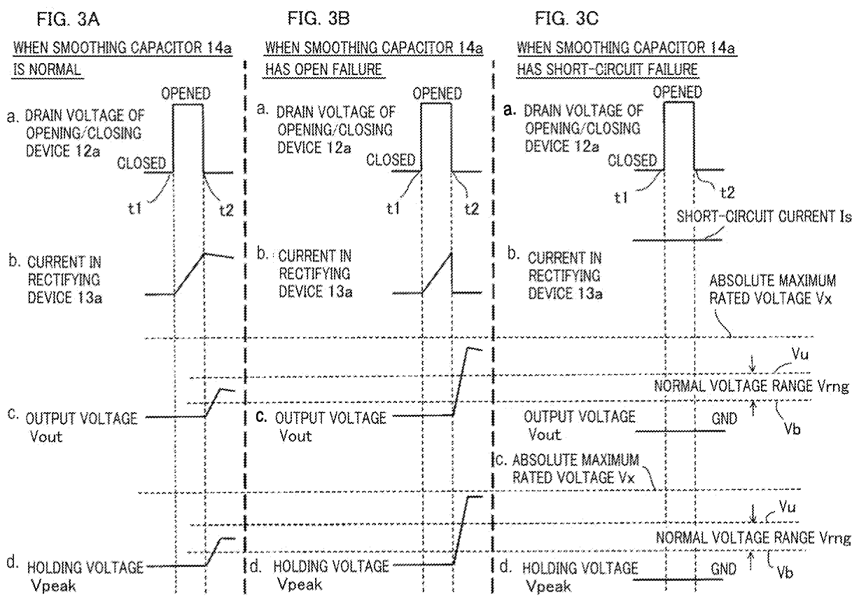

Next, the operation by the voltage conversion apparatus 100 represented in FIG. 1 will be explained. Each of FIGS. 3A, 3B, and 3C is a set of explanatory charts for explaining the operation of the voltage conversion apparatus according to Embodiment 1; FIG. 3A represents the operation by the voltage conversion apparatus 100 at a time when the smoothing capacitor is normal; FIG. 3B represents the operation by the voltage conversion apparatus 100 at a time when the smoothing capacitor has an open failure; FIG. 3C represents the operation by the voltage conversion apparatus 100 at a time when the smoothing capacitor has a short-circuit failure. In each of FIGS. 3A, 3B, and 3C, represents the waveform of a drain voltage of the opening/closing device 12a; (b) represents the waveform of a current in the rectifying device 13a; (c) represents the waveform of the output voltage Vout; (d) represents the waveform of a holding voltage Vpeak.

In FIG. 1, at first, when the switching regulator 10a starts voltage conversion through opening/closing operation by the opening/closing device 12a, the control unit 50 intermittently outputs a pulse signal having a predetermined starting step-up switching frequency Ns1 and a predetermined starting step-up duty Ds1 from the output terminal FC to the gate terminal of the opening/closing device 12a. In the present embodiment, the predetermined starting step-up switching frequency Ns1 and the predetermined starting step-up duty Ds1 in the pulse signal are set in such a way that even when the smoothing capacitor 14a has an open failure, the output voltage Vout is lower than the minimum absolute maximum rated voltage among the respective absolute maximum rated voltages of two or more circuit devices (unrepresented) to which the output voltage Vout is supplied.

Next, the case where the smoothing capacitor 14a is normal will be explained. As represented in FIG. 3A, in accordance with the pulse signal to be intermittently provided from the output terminal FC of the control unit 50 to its gate terminal, the started opening/closing device 12a performs opening/closing operation; in response to the opening/closing operation, its drain voltage changes as represented in (a) of FIG. 3A. Then, the opening/closing operation by the opening/closing device 12a intermittently energizes the induction device 11a; induction energy produced through the intermittent energization is accumulated in the smoothing capacitor 14a and the auxiliary capacitor 60 by way of the rectifying device 13a; as a result, the output voltage Vout is obtained.

When as represented in FIG. 3A, the smoothing capacitor 14a is normal, the opening/closing device 12a opens at a time point t1, as represented in (b) of FIG. 3A, and hence a current in the rectifying device 13a gradually increases from the time point t1; then, when at a time point t2, the opening/closing device 12a closes, the current in the rectifying device 13a gradually decreases; however, the induction energy produced in the induction device 11a is accumulated in the smoothing capacitor 14a and the auxiliary capacitor 60, and the output voltage Vout rises at a gradual gradient from the time point t2, as represented in (c) of FIG. 3A. The holding voltage Vpeak to be held in the voltage holding unit 20 after the time point t2 gradually rises from the time point t2 and then falls within the normal voltage range Vrng; thus, the output voltage Vout is held within the normal voltage range Vrng.

When as represented in FIG. 3B, the smoothing capacitor 14a has an open failure, the induction energy produced in the induction device 11a is not accumulated in the smoothing capacitor 14a but is accumulated only in the auxiliary capacitor 60; therefore, as represented in (c) of FIG. 3B, the output voltage Vout steeply rises from the time point t2 and then exceeds an upper limit value Vu of the normal voltage range Vrng. Accordingly, the holding voltage Vpeak to be held in the voltage holding unit 20 steeply rises from the time point t2 and then exceeds the upper limit value Vu of the normal voltage range Vrng.

Moreover, when as represented in FIG. 30, the smoothing capacitor 14a has a short-circuit failure, a short-circuit current Is continues flowing in the rectifying device 13a, as represented in (b) of FIG. 3C, regardless of whether the opening/closing device 12a is opened or closed; thus, as represented in (c) of FIG. 3C, the output voltage Vout becomes the GND electric potential. Thus, the holding voltage Vpeak to be held in the voltage holding unit 20 remains as the GND electric potential.

As described above, the respective values of the holding voltages Vpeak to be held in the voltage holding unit 20 at a time when the smoothing capacitor 14a is normal, at a time when the smoothing capacitor 14a has an open failure, and at a time when the smoothing capacitor 14a has a short-circuit failure differ from one another. The holding voltage Vpeak, which is the maximum voltage held in the voltage holding unit 20, is divided by the voltage dividing circuit 30 and then is inputted to the input terminal AD of the determination unit 40. Based on the inputted divided voltage of the holding voltage Vpeak, the determination unit 40 determines whether or not the holding voltage Vpeak is within the normal voltage range Vrng. In the case where the Zener diode 33 is provided, the voltage obtained through division by the voltage dividing circuit 30 is limited and is inputted to the determination unit 40; thus, the determination unit 40 is protected from an excessive voltage.

The charges accumulated in the voltage holding capacitor 22 of the voltage holding unit 20 is discharged through the first division resistor 31 and the second division resistor 32; thus, it is desirable that each of the first division resistor 31 and the second division resistor 32 has a large resistance value so as not to affect the determination by the determination unit 40.

In this situation, in the case where the determination unit 40 determines that the holding voltage Vpeak is within the normal voltage range Vrng, it is detected that the smoothing capacitor 14a is normal; then, from the output terminal O1 to the input terminal I, there is inputted a signal that permits a PWM-modulated pulse signal for opening or closing the opening/closing device 12a to be outputted.

The control unit 50 converts the input voltage Vin into a predetermined output voltage grout by controlling the duty of the PWM-modulated pulse signal so that a voltage to be inputted to the feedback terminal FB, i.e., the output voltage Vout becomes a predetermined voltage.

In the case where the holding voltage Vpeak held as a maximum voltage is higher than the upper limit value Vu of the normal voltage range Vrng, the determination unit 40 determines that the smoothing capacitor 14a has an open failure, outputs, from the output terminal O1 to the input terminal I of the control unit 50, a signal for prohibiting the PWM-modulated pulse signal from being outputted so as to stop the PWM-modulated pulse signal from being outputted from the control unit 50, and notifies the external apparatus 200 of the determination result.

Moreover, in the case where the holding voltage Vpeak held as a maximum voltage is lower than a lower limit value Vb of the normal voltage range Vrng, the determination unit 40 determines that the smoothing capacitor 14a has a short-circuit failure; then, as is the case with the open failure, the determination unit 40 outputs, from the output terminal O1 to the input terminal I of the control unit 50, the signal for prohibiting the PWM-modulated pulse signal from being outputted so as to stop the PWM-modulated pulse signal from being outputted from the control unit 50, and notifies the external apparatus 200 of the determination result.

The foregoing operation is the same as the operation in the variant example of the voltage conversion apparatus according to Embodiment 1 represented in FIG. 2.

The voltage conversion apparatus according to Embodiment 1 makes it possible to perform, in a small-size and inexpensive manner, a diagnosis of a failure in the smoothing capacitor, without requiring any large-scale diagnosis circuit and expanding a failure throughout the apparatus.

### Embodiment 2

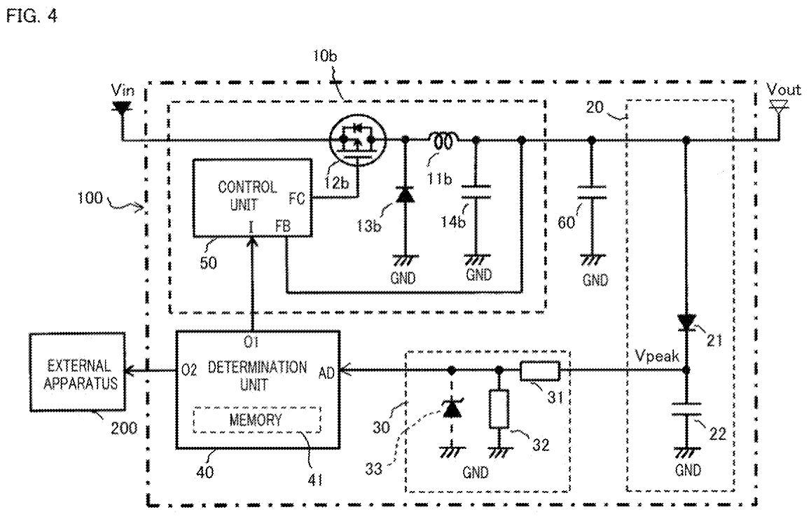

FIG. 4 is a configuration diagram representing the configuration of a voltage conversion apparatus according to Embodiment 2; the same reference characters as those in FIG. 1 denote the same or equivalent elements. A voltage conversion apparatus 100 in FIG. 4 differs from the voltage conversion apparatus 100 according to Embodiment 1 represented in FIG. 1 in that the switching regulator is a step-down switching regulator 10b.

At first, there will be explained the function and the configuration example of the switching regulator 10b with which the voltage conversion apparatus according to Embodiment 2 differs from the voltage conversion apparatus according to Embodiment 1. In FIG. 4, the switching regulator 10b steps down the input voltage Vin to a predetermined output voltage Vout, and is a step-down chopper circuit including an induction device 11b, an opening/closing device 12b, a rectifying device 13b, a smoothing capacitor 14b, and the control unit 50.

As is the case with Embodiment 1, the control unit 50 is a so-called PWM controller that performs a PWM modulation so that a voltage inputted to the feedback terminal FB becomes a predetermined voltage and then outputs a PWM-modulated pulse signal from the output terminal FC; the control unit 50 has a function of outputting or stopping the pulse signal in accordance with a signal inputted to the input terminal I.

The smoothing capacitor 14b is to smooth induction energy produced through opening/closing operation by the opening/closing device 12b; thus, it is desirable to adopt a capacitor such as an electrolytic capacitor whose capacity can readily be increased. The rectifying device 13b is a diode; however, it may be allowed that the rectifying device 13b is configured in another manner such as a synchronous rectification method utilizing MOS-FET. In addition, in the case of the step-down switching regulator 10b represented in FIG. 2, it is desirable that the opening/closing device 12b is a P-type MOS-FET that can readily be driven.

Next, electrical connection relationships in the switching regulator 10b will be explained. The input voltage Vin is applied to the source terminal of the opening/closing device 12b. The gate terminal of the opening/closing device 12b is connected with the output terminal FC of the control unit 50. The drain terminal of the opening/closing device 12b is connected with the cathode terminal of the rectifying device 13b and one end of the induction device 11b. The output voltage Vout to be outputted from the other end of the induction device 11b is applied to one end of the smoothing capacitor 14b and the feedback terminal FB of the control unit 50. The anode terminal of the rectifying device 13b and the other end of the smoothing capacitor 14b are connected with GND.

It may be allowed that the voltage holding unit 20 is replaced by a voltage holding unit having a configuration the same as that of the voltage holding unit 20a represented in foregoing FIG. 2.

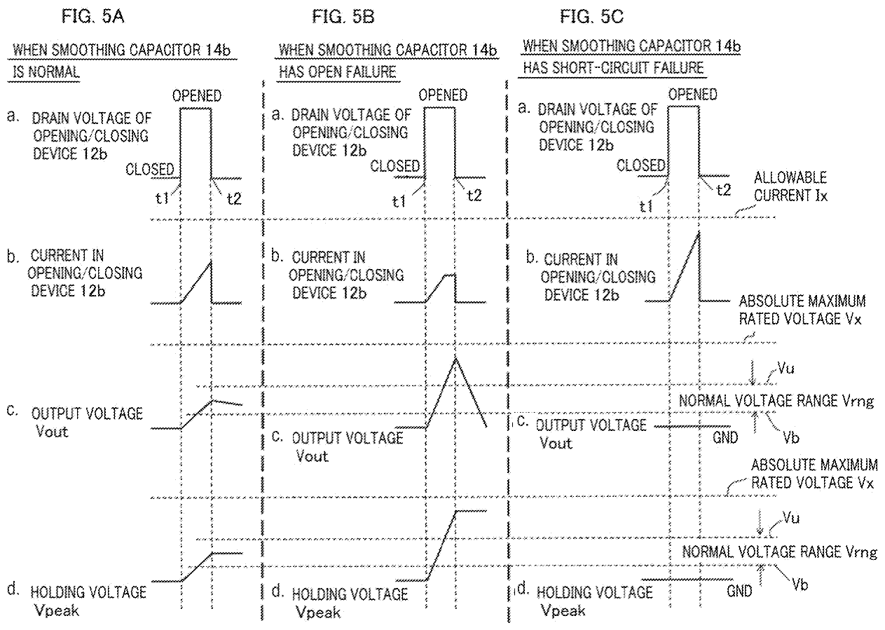

Next, the operation by the voltage conversion apparatus 100 according to Embodiment 2 represented in FIG. 4 will be explained. Each of FIGS. 5A, 5B, and 5C is a set of explanatory charts for explaining the operation of the voltage conversion apparatus according to Embodiment 2; FIG. 5A represents the operation of the voltage conversion apparatus 100 at a time when the smoothing capacitor is normal; FIG. 5B represents the operation of the voltage conversion apparatus 100 at a time when the smoothing capacitor is opened; FIG. 5C represents the operation of the voltage conversion apparatus 100 at a time when the smoothing capacitor has a short-circuit failure. In each of FIGS, 5A, 5B, and 5C, (a) represents the waveform of a drain voltage of the opening/closing device 12b; (b) represents the waveform of a current in the opening/closing device 12b; (c) represents the waveform of the our voltage Vout; (d) represents the waveform of the holding voltage Vpeak.

At first, when the opening/closing operation by the opening/closing device 12b in the switching regulator 10b is started, the control unit 50 outputs a pulse signal having a predetermined starting step-down switching frequency Ns2 and a predetermined starting step-down duty Ds2 to the opening/closing device 12b. In the present embodiment, the predetermined starting step-down switching frequency Ns2 and the predetermined starting step-down duty Ds2 are set in such a way that even when the smoothing capacitor 14b has an open failure, the output voltage Vout is lower than a minimum absolute maximum rated voltage Vx among the respective absolute maximum rated voltages of two or more circuit devices connected with the output voltage Vout and in such a way that even when the smoothing capacitor 14b has a short-circuit failure, the current in the opening/closing device 12b is smaller than an allowable current Ix.

Next, the case where the smoothing capacitor 14b is normal will be explained. As represented in FIG. 5A, in accordance with the pulse signal to be intermittently provided from the output terminal FC of the control unit 50 to its gate terminal, the started opening/closing device 12b performs opening/closing operation; in response to the opening/closing operation, the drain voltage of the opening/closing device 12b changes as represented in (a) of FIG. 5A. Then, the opening/closing operation by the opening/closing device 12b intermittently energizes the induction device 11b; induction energy produced through the intermittent energization is accumulated in the smoothing capacitor 14b and the auxiliary capacitor 60; as a result, the output voltage Vout is obtained.

When the smoothing capacitor 14b is normal, the opening/closing device 12b closes at a time point t1, as represented in (b) of FIG. 5A, and hence a current in the rectifying device 13b gradually increases from the time point t1; then, when at a time point t2, the opening/closing device 12b opens, the current in the rectifying device 13b gradually decreases; however, the induction energy produced in the induction device 11b is accumulated in the smoothing capacitor 14b and the auxiliary capacitor 60, and the output voltage Vout rises at a gradual gradient from the time point t2, as represented in (c) of FIG. 5A. The holding voltage Vpeak to be held in the voltage holding unit 20 after the time point t2 gradually rises from the time point t2 and then falls within the normal voltage range Vrng; thus, the output voltage Vout is held within the normal voltage range Vrng.

When as represented in FIG. 5A, the smoothing capacitor 14b has an open failure, the induction energy produced in the induction device 11b is not accumulated in the smoothing capacitor 14b but is accumulated only in the auxiliary capacitor 60; therefore, as represented in (c) of FIG. 5B, the output voltage Vout steeply rises from the time point t1 and exceeds the upper limit value Vu of the normal voltage range Vrng; then, the output voltage Vout steeply decreases. Accordingly, the holding voltage Vpeak to be held in the voltage holding unit 20 steeply rises from the time point t1 and then exceeds the upper limit value Vu of the normal voltage range Vrng.

Moreover, when as represented in FIG. 5C, the smoothing capacitor 14b has a short-circuit failure, a current corresponding to the short-circuit current flows in the opening/closing device 12b, as represented in (b) of FIG. 5C, and the output voltage Vout becomes the GND electric potential. Thus, the holding voltage Vpeak to be held in the voltage holding unit 20 remains as the GND electric potential.

As described above, the respective values of the holding voltages Vpeak to be held in the voltage holding unit 20 at a time when the smoothing capacitor 14b is normal, at a time when the smoothing capacitor 14b has an open failure, and at a time when the smoothing capacitor 14b has a short-circuit failure differ from one another. The holding voltage Vpeak, which is the maximum voltage held in the voltage holding unit 20, is divided by the voltage dividing circuit 30 and then is inputted to the input terminal AD of the determination unit 40. Based on the inputted divided voltage of the holding voltage Vpeak, the determination unit 40 determines whether or not the holding voltage Vpeak is within the normal voltage range Vrng. In the case where the Zener diode 33 is provided, the voltage obtained through division by the voltage dividing circuit 30 is limited and is inputted to the determination unit 40; thus, the determination unit 40 is protected from an excessive voltage.

The charges accumulated in the voltage holding capacitor 22 of the voltage holding unit 20 is discharged through the first division resistor 31 and the second division resistor 32; thus, it is desirable that each of the first division resistor 31 and the second division resistor 32 has a large resistance value so as not to affect the determination by the determination unit 40.

In this situation, in the case where the determination unit 40 determines that the holding voltage Vpeak is within the normal voltage range Vrng, it is detected that the smoothing capacitor 14b is normal; then, from the output terminal O1 to the input terminal I, there is inputted a signal that permits a PWM-modulated pulse signal for opening or closing the opening/closing device 12b to be outputted.

The control unit 50 converts the input voltage Vin into a predetermined output voltage Vout by controlling the duty of the PWM-modulated pulse signal so that a voltage to be inputted to the feedback terminal FB, i.e., the output voltage Vout becomes a predetermined voltage.

In the case where the holding voltage Vpeak held as a maximum voltage is higher than the upper limit value Vu of the normal voltage range Vrng, the determination unit 40 determines that the smoothing capacitor 14b has an open failure, outputs, from the output terminal O1 to the input terminal I of the control unit 50, a signal for prohibiting the PWM-modulated pulse signal from being outputted so as to stop the PWM-modulated pulse signal from being outputted from the control unit 50, and notifies the external apparatus 200 of the determination result.

Moreover, in the case where the holding voltage Vpeak held as a maximum voltage is lower than a lower limit value Vb of the normal voltage range Vrng, the determination unit 40 determines that the smoothing capacitor 14b has a short-circuit failure; then, as is the case with the open failure, the determination unit 40 outputs, from the output terminal O1 to the input terminal I of the control unit 50, the signal for prohibiting the PWM-modulated pulse signal from being outputted so as to stop the PWM-modulated pulse signal from being outputted from the control unit 50, and notifies the external apparatus 200 of the determination result.

As described above, as is the case with the voltage conversion apparatus according to Embodiment 1, the voltage conversion apparatus 100 according to Embodiment 2 makes it possible to perform, in a small-size and inexpensive manner, a diagnosis of a failure in the smoothing capacitor, without requiring any large-scale diagnosis circuit and expanding a failure throughout the apparatus.

It should be understood that the various features, aspects and functions described in one or more of the individual embodiments are not limited in their applicability to the particular embodiment, but instead can be applied, alone or in various combinations to one or more of the embodiments. Therefore, an infinite number of unexemplified variant examples are conceivable within the range of the technology disclosed in the present application. For example, there are included the case where at least one constituent element is modified, added, or omitted and the case where at least one constituent element is extracted and then combined with constituent elements of other embodiments.

What is claimed is:

1. A voltage conversion apparatus comprising:
a switching regulator including
an induction device that is intermittently energized through opening/closing operation by an opening/closing device so as to produce induction energy,
a smoothing capacitor that accumulates the induction energy produced by the induction device and smooths the induction energy, and
a control unit that controls opening/closing operation by the opening/closing device;
an auxiliary capacitor that supports smoothing by the smoothing capacitor;
a voltage holding unit that holds a maximum voltage of the output voltage; and
a determination unit that determines whether or not the maximum voltage held by the voltage holding unit is within a predetermined voltage range,
wherein the switching regulator converts an input voltage supplied from an outside into a predetermined voltage to be outputted as an output voltage,
wherein when starting control of opening/closing operation by the opening/closing device, the control unit makes the opening/closing device perform the opening/closing operation, based on a predetermined starting switching frequency and a predetermined starting duty, and
wherein the determination unit detects a failure in the smoothing capacitor by determining that the held maximum voltage is out of the voltage range.

2. The voltage conversion apparatus according to claim 1,
wherein the switching regulator is a step-down type, and
wherein the starting switching frequency and the starting duty are set in such a way that when the smoothing capacitor is short-circuited, a current in the opening/closing device is smaller than an allowable current thereof.

3. The voltage conversion apparatus according to claim 1, wherein the starting switching frequency and the starting duty are set in such a way that when the smoothing capacitor is opened, the output voltage is the same as or lower than a minimum absolute maximum rated voltage among respective absolute maximum rated voltages of two or more circuit devices to which the output voltage is supplied.

4. The voltage conversion apparatus according to claim 2, wherein the starting switching frequency and the starting duty are set in such a way that when the smoothing capacitor is opened, the output voltage is the same as or lower than a minimum absolute maximum rated voltage among respective absolute maximum rated voltages of two or more circuit devices to which the output voltage is supplied.

5. The voltage conversion apparatus according to claim 1, wherein an upper limit value of the predetermined voltage range is the same as or lower than respective absolute maximum rated voltages of two or more circuit devices to which the output voltage is supplied.

6. The voltage conversion apparatus according to claim 2, wherein an upper limit value of the predetermined voltage range is the same as or lower than respective absolute maximum rated voltages of two or more circuit devices to which the output voltage is supplied.

7. The voltage conversion apparatus according to claim 3, wherein an upper limit value of the predetermined voltage range is the same as or lower than respective absolute maximum rated voltages of two or more circuit devices to which the output voltage is supplied.

8. The voltage conversion apparatus according to claim 4, wherein an upper limit value of the predetermined voltage range is the same as or lower than respective absolute maximum rated voltages of two or more circuit devices to which the output voltage is supplied.

9. The voltage conversion apparatus according to claim 1, wherein the determination unit is configured in such a way that a memory for storing values of the voltage range is provided therein and that the voltage range can be changed by rewriting the values of the voltage range stored in the memory.

10. The voltage conversion apparatus according to claim 2, wherein the determination unit is configured in such a way that a memory for storing values of the voltage range is provided therein and that the voltage range can be changed by rewriting the values of the voltage range stored in the memory.

11. The voltage conversion apparatus according to claim 1, wherein when detecting a failure in the smoothing capacitor, the determination unit notifies an outside of the voltage conversion apparatus of the detection result.

12. The voltage conversion apparatus according to claim 2, wherein when detecting a failure in the smoothing capacitor, the determination unit notifies an outside of the voltage conversion apparatus of the detection result.

13. The voltage conversion apparatus according to claim 1, further comprising a voltage dividing circuit, wherein the maximum voltage held in the voltage holding unit is divided by the voltage dividing circuit and then is inputted to the determination unit.

14. The voltage conversion apparatus according to claim 2, further comprising a voltage dividing circuit, wherein the maximum voltage held in the voltage holding unit is divided by the voltage dividing circuit and then is inputted to the determination unit.

15. The voltage conversion apparatus according to claim 13,
wherein the voltage dividing circuit has a Zener diode, and
wherein the Zener diode provides an upper to a voltage to be inputted to the determination unit.

16. The voltage conversion apparatus according to claim 14,
wherein the voltage dividing circuit has a Zener diode, and
wherein the Zener diode provides an upper limit to a voltage to be inputted to the determination unit.

17. The voltage conversion apparatus according to claim 1, further comprising an auxiliary capacitor that is connected in parallel with the smoothing capacitor and supports smoothing operation by the smoothing capacitor.

18. The voltage conversion apparatus according to claim 2, further comprising an auxiliary capacitor that is connected in parallel with the smoothing capacitor and supports smoothing operation by the smoothing capacitor.

19. The voltage conversion apparatus according to claim 3, further comprising an auxiliary capacitor that is connected in parallel with the smoothing capacitor and supports smoothing operation by the smoothing capacitor.

20. The voltage conversion apparatus according to claim 4, further comprising an auxiliary capacitor that is connected in parallel with the smoothing capacitor and supports smoothing operation by the smoothing capacitor.
